(19) United States
(12) Patent Application Publication
(10) Pub. No.: US 2026/0058099 A1
(43) Pub. Date: Feb. 26, 2026

(54) CONTROL DEVICE FOR CONTROLLING A PLASMA PROCESS SUPPLY SYSTEM, A PLASMA PROCESS SUPPLY SYSTEM HAVING SUCH A CONTROL DEVICE, AND A METHOD FOR OPERATING A CONTROL DEVICE

(71) Applicant: TRUMPF Hüttinger GmbH + Co. KG, Freiburg (DE)

(72) Inventor: Alexander ALT, Freiburg (DE)

(21) Appl. No.: 19/375,527

(22) Filed: Oct. 31, 2025

Related U.S. Application Data
(63) Continuation of application No. PCT/EP2024/062150, filed on May 2, 2024.

(30) Foreign Application Priority Data
May 3, 2023 (DE) 10 2023 111 487.5

(51) Int. Cl. H01J 37/32; H03H 7/38

(52) U.S. Cl. CPC H01J 37/32183; H01J 37/321; H01J 37/32155; H03H 7/38; H01J 2237/24564

(57) ABSTRACT

A control device for controlling a plasma process supply system, including a radio-frequency (RF) generator and an impedance matching circuit configured for connection to a load. The control device is configured to determine a supply power of the RF generator and an output power of the impedance matching circuit. The control device is configured to change a frequency of the RF generator and/or to adjust the impedance matching circuit such that an overall efficiency of the plasma process supply system, which results from the determined supply power of the RF generator and the output power of the impedance matching circuit, is increased.

### CROSS REFERENCE TO RELATED APPLICATIONS

This application is a continuation of International Application No. PCT/EP2024/062150 (published as WO 2024/227892 A1), filed on May 2, 2024, and claims benefit to German Patent Application No. DE 10 2023 111 487.5, filed on May 3, 2023. The aforementioned applications are hereby incorporated by reference herein in their entirety.

### FIELD

The invention relates to a control device for controlling a plasma process supply system, a plasma process supply system having such a control device, and a method for operating a control device.

### BACKGROUND

The surface treatment of workpieces using plasma and gas lasers are industrial processes in which, in particular in a plasma chamber, a plasma is generated either using direct current or a radio-frequency alternating signal having an operating frequency in the range of several tens of kHz up to the GHz range, in particular up to 100 GHz.

The plasma chamber is connected to a radio-frequency generator (RF generator) via additional electronic components such as coils, capacitors, cables or transformers. These additional components can be oscillating circuits, filters, or impedance matching circuits.

The plasma process has the problem that the electrical load impedance of the plasma chamber (the plasma=consumer) that takes place during the process, depends on the conditions in the plasma chamber and can vary greatly. In particular, the properties of the workpiece, electrodes, and gas conditions are taken into account.

Radio-frequency generators have a limited operating range with respect to the impedance of the connected electrical load (=consumer). If the load impedance leaves a permissible range, the RF generator may be damaged or even destroyed.

For this reason, an impedance matching circuit (matchbox) is usually required to transform the impedance of the load to a nominal impedance of the generator output.

Various impedance matching circuits are known. The impedance matching circuits can be fixed and have a predetermined transformation effect, i.e., they consist of electrical components, in particular coils and capacitors, which are not changed during operation. This is particularly useful for operations that are always consistent, such as with a gas laser. Furthermore, impedance matching circuits are known in which at least some of the components of the impedance matching circuits are mechanically variable. For example, motor-driven rotary capacitors are known, the capacitance value of which can be changed by changing the arrangement of the capacitor plates relative to one another.

A plasma can, in a general sense, be assigned to three impedance ranges. There are very high impedances before ignition. In normal operation, i.e., during operation as intended with plasma, lower impedances are present. Very small impedances can occur in the case of undesirable local discharges (arcs) or plasma fluctuations. In addition to these three identified impedance ranges, other special conditions with other associated impedance values can occur. If the load impedance changes suddenly and the load impedance or the transformed load impedance moves out of a permissible impedance range, the RF generator or transmission devices between the RF generator and the plasma chamber can be damaged. There are also stable states of the plasma that are not desired.

An impedance matching circuit is described for example in the document DE 10 2009 001 355 A1.

It is also known that plasma processes require a lot of energy, which is playing an increasingly important role today. Losses occur in particular due to high idle currents flowing in the impedance matching circuit, which reduce the efficiency of the impedance matching circuit. To transfer the desired power into the plasma, the radio-frequency generator must therefore provide a higher output power, which further increases the power loss.

### SUMMARY

In an embodiment, the present disclosure provides a control device for controlling a plasma process supply system, comprising a radio-frequency (RF) generator and an impedance matching circuit configured for connection to a load. The control device is configured to determine a supply power of the RF generator and an output power of the impedance matching circuit. The control device is configured to change a frequency of the RF generator and/or to adjust the impedance matching circuit such that an overall efficiency of the plasma process supply system, which results from the determined supply power of the RF generator and the output power of the impedance matching circuit, is increased.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates an exemplary embodiment of a plasma process supply system according to the present disclosure having a control device according to the present disclosure;

FIG. 2A, and FIG. 2B illustrate various exemplary embodiments of how an impedance matching circuit can be constructed;

FIG. 3, and FIG. 4 illustrate exemplary embodiments of how a measuring unit can be configured to measure a current and a voltage;

FIG. 5 illustrates an exemplary embodiment of exemplary efficiency curves; and

FIG. 6 illustrates a flowchart for a method which explains the operation of the control device.

### DETAILED DESCRIPTION

In an embodiment, the present disclosure provides a plasma process that is as energy-efficient as possible.

The control device according to an embodiment of the present disclosure serves to control a plasma supply system which comprises an RF generator and an impedance matching circuit and is used for connection to a load, in particular to a plasma chamber. The control device is designed to determine a supply power of the RF generator and an output power of the impedance matching circuit. The term “supply power” refers in particular to the power required to operate the RF generator. This particularly refers to the power that the at least one power supply of the RF generator receives from or delivers to the (public) power grid. If the RF generator has several power supplies, the “supply power” is the sum of the power that the power supplies of the RF generator receive from or deliver to the (public) power grid. The term “output power” refers to the power that originates from the power delivered by the RF generator and is output by the impedance matching circuit. If a plurality of signals from different RF generators or DC generators are fed to the impedance matching circuit, the signals from the other RF generators or DC generators should be disregarded when determining the output power. These other signals can be ignored particularly easily because they have a different frequency. The control device is further designed to adjust the RF generator and/or the impedance matching circuit, in particular by changing the frequency of the RF generator, such that an overall efficiency of the plasma process supply system, which results from the determined supply power of the RF generator and the output power of the impedance matching circuit, is increased.

It is particularly advantageous here that the control device is designed to regulate the RF generator and/or the impedance matching circuit so as to optimize the overall efficiency. Thus, the control device is designed to determine the overall efficiency based on the supply power of the RF generator and the output power of the impedance matching circuit. The control device therefore takes into account both the RF generator and the impedance matching circuit. Thus, no individual optimization of the RF generator or the impedance matching circuit takes place. Studies have shown that even a reduction in the efficiency of the impedance matching circuit, which is determined from an input power and an output power of the impedance matching circuit, can lead to an increase in the overall efficiency if the RF generator or the impedance matching circuit are adjusted accordingly. In other words, a reduction in the efficiency of one component (RF generator or impedance matching circuit) can be accepted because the efficiency of the other component increases significantly at the same time, resulting in an improvement of the overall efficiency.

Control devices are described in the prior art, in particular in U.S. Ser. No. 10/818,477B2, US20210134563A1 and US20180053633A1.

In an advantageous embodiment, the control device is designed to calculate the overall efficiency of the plasma process supply system based on the determined supply power and the output power. In particular, the output power is divided by the supply power. It is provided that a large number of measured values for the supply power and for the output power are averaged before the overall efficiency is calculated.

In an advantageous embodiment, the control device is designed to determine the output power of the RF generator, in particular the forward power and the reflected power or a quantity related to the reflected power.

In an advantageous embodiment, the control device is designed to adjust, in particular to regulate, the output power of the RF generator. The control can, for example, be carried out in such a way that the reflected power is minimized or falls below a threshold value.

In an advantageous embodiment, the control device is designed to change, in particular continuously, the frequency of the RF generator during operation. For example, a frequency change can occur more than 5 times, 10 times, 100 times, 200 times, 500 times, or more than 1000 times per second. The control device is further designed to check, in particular continuously, whether or not the overall efficiency improves after a frequency change. This continuous check can, for example, occur more than 5 times, 10 times, 100 times, 200 times, 500 times, or more than 1000 times per second. Preferably, the continuous check is always carried out after a change in frequency, wherein, further preferably, a certain period of time is waited after the change in frequency before checking the overall efficiency. This means that overall operational efficiency can always be optimized. Changing the frequency of the RF generator is also very easy and very quick. The control device is preferably designed to change the frequency of the RF generator only within a certain range. This range is preferably selected depending on the amplifier elements used. This ensures that the RF generator is not operated outside the specifications thereof, which could, for example, lead to damage to the RF generator.

In an advantageous embodiment, the control device is designed to further change the frequency in the same direction if the overall efficiency has improved. For example, if the frequency is increased and the overall efficiency improves, the frequency is further increased in a further step. Additionally or alternatively, the control device is designed to change the frequency in the opposite direction if the overall efficiency has deteriorated. For example, if the frequency is increased and the overall efficiency deteriorates as a result, the frequency is reduced in the next step.

In an advantageous embodiment, the control device is designed to select a step size by which the frequency of the signal which the RF generator outputs to the impedance matching circuit is changed, depending on a change in the overall efficiency. Preferably, the larger the step size, the more the overall efficiency changes. This causes the system to oscillate quickly.

In an advantageous embodiment, the control device is designed to set the frequency only within a specific frequency range. This frequency range can further preferably be specified by a user and/or a driver for controlling the RF generator. This prevents the RF generator from operating outside the specifications thereof.

In an advantageous embodiment, the control device comprises an AI module which is factory-trained to adjust the RF generator and/or the impedance matching circuit at least based on the supply power and the output power, in particular to change the frequency of the RF generator. During training, the AI module is supplied with different values for the supply power of the RF generator and the output power of the impedance matching circuit. At the same time, the AI module is informed of the frequency at which the RF generator should be operated or whether the frequency at which the RF generator should be operated should be increased, decreased, or left the same. Additionally or alternatively, the AI module can also be informed how the impedance matching circuit is to be set, in particular how the transformation ratio is to be selected. The whole procedure can also be made dependent on the current plasma process. During operation, the AI module is supplied with the supply power of the RF generator and the output power of the impedance matching circuit. This happens at the input nodes. The type of the respective plasma process can also be supplied to the AI module at the input node. The AI module comprises a plurality of intermediate nodes and at least one output node at which the frequency to be set for the RF generator can be output or the information as to whether the frequency should be increased or decreased. Additionally or alternatively, the transformation ratio of the impedance matching circuit or the information as to whether the transformation ratio should be increased or decreased can be output in the at least one output node.

In an advantageous embodiment, the control device is designed to change the frequency of the RF generator only when the overall efficiency exceeds a threshold value. ‘Exceeding’ here means both a transition from larger to smaller or from smaller to larger values. This prevents the frequency from constantly changing. Additionally or alternatively, this can also apply to a change in the transformation ratio of the impedance matching circuit. For example, if the overall efficiency is greater than 70%, there is no need to change the frequency of the RF generator and/or the transformation ratio of the impedance matching circuit.

In an advantageous embodiment, the control device is designed to control the impedance matching circuit in such a way that a transformation ratio between an input impedance of the impedance matching circuit and an output impedance of the impedance matching circuit can be changed during operation, wherein the control device is further designed to check whether or not the overall efficiency improves after a change in the transformation ratio. The input impedance and/or the output impedance of the impedance matching circuit can change in the process. But this is not absolutely necessary.

In an advantageous embodiment, the control device is designed to control the impedance matching circuit in such a way that the input impedance and/or the output impedance remains unchanged when the transformation ratio changes. For this purpose, the impedance matching circuit preferably comprises at least one transformation stage, so that the input impedance is transformed to at least one first intermediate impedance, which in turn is then transformed to the output impedance. The input impedance can still correspond to the nominal impedance of the RF generator, such as 50 ohms, and the output impedance can still correspond to the plasma impedance. By changing the transformation ratio from the input impedance to at least one first intermediate impedance, the overall efficiency can still be increased.

In an advantageous embodiment, the impedance matching circuit comprises a first transformation stage which is designed to transform an input impedance into a first intermediate impedance. The impedance matching circuit can comprise a second transformation stage designed to transform the first intermediate impedance into a second intermediate impedance. The impedance matching circuit can comprise a third transformation stage designed to transform the second intermediate impedance into an output impedance. The control device is designed to control the impedance matching circuit in such a way that, for a predetermined input and output impedance, the transformation path of the first transformation stage and/or the second transformation stage and/or the third transformation stage changes, wherein the control device then redetermines the overall efficiency of the plasma process supply system after such a change.

In an advantageous embodiment, the supply power is an active power. Additionally or alternatively, the output power is an active power.

In an advantageous embodiment, the control device comprises a first measuring unit. The first measuring unit is designed to determine the supply power from an alternating voltage and an alternating current which can be obtained from the (public) power grid and which are present at the input of a power supply unit of the RF generator. In this case, the overall efficiency also includes the efficiency of at least one power supply of the RF generator. Alternatively, the first measuring unit is designed to determine the supply power from a direct voltage and a direct current which are present at the output of the power supply of the RF generator and which serve to supply at least one RF amplifier of the RF generator. In this case, the supply power can be determined more easily. The at least one power supply unit is designed in particular to transform a mains supply voltage with a frequency of, for example, 50 Hz or 60 Hz into a regulated direct voltage, which can also be referred to as intermediate circuit voltage. This direct voltage is then fed to at least one RF amplifier, which converts it into RF power to amplify an RF signal.

In an advantageous embodiment, the control device comprises at least a second measuring unit. The second measuring unit comprises at least one directional coupler or a current sensor and a voltage sensor. The control device is designed to determine the output power based on the measurement result of the at least one directional coupler or the current sensor and the voltage sensor.

In an advantageous embodiment, the second measuring unit can be arranged at the output of the impedance matching circuit. Alternatively, the second measuring unit can be arranged at the input of the impedance matching circuit and the control device is designed to determine the output power based on the current transformation ratio of the impedance matching circuit.

In an advantageous embodiment, the voltage sensor of the second measuring unit is a capacitive voltage divider, wherein a first capacitance is formed by an electrically conductive ring or cylinder through which a cable, carrying the RF power, can be routed. In addition, the current sensor of the second measuring unit is a coil arranged around the conductive ring or cylinder. This design enables a contactless measurement of current and voltage.

In an advantageous embodiment, the control device is designed to determine a reflection factor, in particular at the output of the RF generator. The control device is designed to adjust the RF generator and/or the impedance matching circuit, in particular to change the frequency of the RF generator, so that the reflection factor is reduced, wherein the control device is further designed to adjust the RF generator and/or the impedance matching circuit so that the reflection factor is increased when the overall efficiency improves at the same time. It is particularly advantageous that an increasing reflection factor is also permitted when the overall efficiency improves at the same time.

The plasma process supply system according to an embodiment of the present disclosure comprises the control device described above. The plasma supply system comprises an RF generator and an impedance matching circuit. The RF generator is connected to the impedance matching circuit via a first cable connection. The impedance matching circuit can be connected to a load, in particular in the form of a plasma chamber, via a second cable connection. It is particularly advantageous that the control device acts as a kind of central control device and controls both the RF generator and the impedance matching circuit.

In an advantageous embodiment of the plasma process supply system, the RF generator comprises at least one power supply and at least one RF amplifier. The at least one power supply comprises an input for connection to a (public) power grid and an output for connection to the at least one RF amplifier. The at least one power supply is designed to convert an alternating voltage at the input into a (regulatable) direct voltage and to output the direct voltage at the output and to supply it to the at least one RF amplifier. The control device is designed to determine the supply power at the input or at the output or between the input and the output.

In an advantageous embodiment of the plasma process supply system, the impedance matching circuit comprises at least one or more adjustable reactances to change the transformation ratio for the impedance between an input, to which the RF generator is connected, and an output, to which the load can be connected. The reactances are mechanically adjustable and/or electrically adjustable and are formed in particular by at least one varactor and/or at least one switchable inductance and/or capacitance and/or at least one PIN diode. If the reactance is a capacitance, its level can be changed, for example, by motor-driven adjustment of the plate spacing. The term “adjustable” can also be understood as a switching on and/or off of a reactance.

The method according to an embodiment of the present disclosure serves to operate the control device mentioned at the outset for controlling the plasma supply system with an RF generator and an impedance matching circuit. In a first step, the supply power of the RF generator is determined. Furthermore, the output power of the impedance matching circuit is determined. In a second process step, the RF generator is adjusted, in particular by changing the frequency of the RF generator. Additionally or alternatively, the impedance matching circuit is adjusted. This results in an increase in the overall efficiency of the plasma process supply system, which results from the determined supply power of the RF generator and the output power of the impedance matching circuit.

Embodiments of the present disclosure are described below by way of example with reference to the drawings.

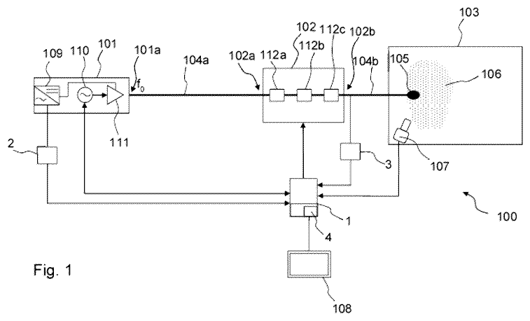

FIG. 1 shows a plasma process supply system 100 which comprises a control device 1. The plasma generation system 100 further comprises an RF generator 101, an impedance matching circuit 102 and at least one consumer 103, in particular in the form of a plasma chamber. The RF generator 101 is designed to supply an RF signal, in particular in the form of a CW signal, with a nominal power P_{Nominal} and a frequency f₀, and to output it at an output terminal 101a. The impedance matching circuit 102 comprises an input terminal 102a, wherein the RF generator 101 is connected to the input terminal 102a via a first cable connection 104a. The impedance matching circuit 102 further comprises an output terminal 102b. The output terminal 102b is connected to the at least one consumer 103 via a second cable connection 104b. The first and/or second cable connection 104a, 104b can comprise one or a plurality of cables, for example connected in series and/or in parallel. Coaxial cables are preferably used.

The consumer 103, i.e., the plasma chamber, comprises at least one electrode 105 for generating a plasma 106. The electrode 105 is (galvanically) connected to the output terminal 102b of the impedance matching circuit 102. In this exemplary embodiment, a camera system 107 is arranged in the plasma chamber, which is designed to monitor the plasma 106.

The control device 1 is preferably a processor and/or FPGA and/or microcontroller and/or ASIC. The control device 1 can also comprise a storage unit.

The control device 1 is designed to control the RF generator 101, in particular to activate or deactivate it. Additionally or alternatively, the control device 1 is also designed to change the power and/or frequency of the RF signal by appropriately controlling the RF generator 101. Additionally or alternatively, the control device 1 is designed to change the waveform (type of RF signal, modulation of the RF signal) of the RF signal by appropriately controlling the RF generator 101.

The RF generator 101 comprises a power supply 109 which is designed to transform an alternating current into a (regulated) direct current and an alternating voltage into a (regulated) direct voltage. The RF generator 101 also includes a signal generating device 110 and an RF amplifier 111. The signal generating device 110 is designed, in particular, to generate the CW signal and to output it to the RF amplifier 111. The RF amplifier 111 is designed to amplify the CW signal to a specific level and to transmit it to the impedance matching circuit 102 via the output terminal 101a. The RF amplifier 111 is powered by the power supply 109.

The control device 1 is likewise preferably designed to control the impedance matching circuit 102. In particular, the control device 1 is designed to change the transformation ratio within the impedance matching circuit 102.

The control device 1 also comprises a first measuring unit 2. The first measuring unit 2 is designed to determine the supply power from an alternating voltage and an alternating current which the power supply unit 109 of the RF generator 101 draws from the (public) power grid. Alternatively, the first measuring unit 2 is designed to determine the supply power from a direct voltage and a direct current that are provided at the output of the power supply 109 of the RF generator 101 and used to supply the at least one RF amplifier 111. The first measuring unit 2 can, for example, comprise a shunt resistor for measuring the direct current and, for example, a voltage divider for measuring the direct voltage.

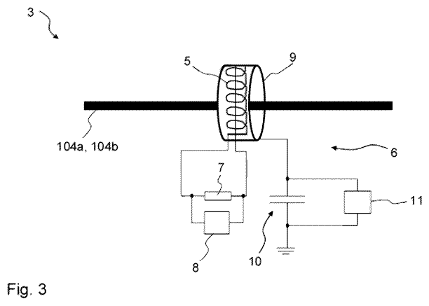

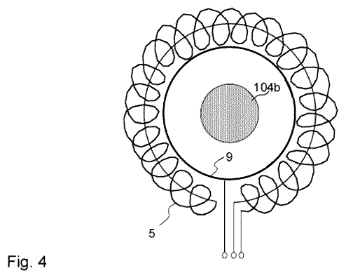

The control device 1 also comprises a second measuring unit 3. The second measuring unit 3 comprises at least one directional coupler or a current sensor 5 and a voltage sensor 6. A design with a current sensor 5 and a voltage sensor 6 is shown in FIGS. 3 and 4. The control device 1 is designed to determine, in particular to calculate, the output power at the output of the impedance matching circuit 102 based on the measurement result of the at least one directional coupler or the current sensor 5 and the voltage sensor 6. In FIG. 1, the second measuring unit 3 is arranged at the output of the impedance matching circuit 102. The second measuring unit 3 could also be arranged at the input of the impedance matching circuit 102, wherein the control device 1 is in this case designed to determine the output power at the output terminal 102b of the impedance matching circuit 102 based on the current transformation ratio of the impedance matching circuit 102.

The supply power is preferably an active power. The output power is likewise preferably an active power.

As explained, the control device 1 is designed to determine, in particular to measure, a supply power of the RF generator 101 and an output power of the impedance matching circuit 102. The control device 1 is then designed to adjust the RF generator 101 and/or the impedance matching circuit 102, in particular to change the frequency of the RF generator 101, so that an overall efficiency of the plasma process supply system 100, which results from the determined supply power of the RF generator 101 and the output power of the impedance matching circuit 102, is increased.

The plasma generating system 100 preferably also comprises an operating unit 108. The operating unit 108 is preferably a screen, in particular a touch-sensitive screen. In addition to a screen, the operating unit 108 can also comprise input means such as a keyboard and/or mouse. The operating unit 108 can also be a web server that provides data and receives user input. The control device 1 is designed to display current settings of the RF generator 101 and/or the impedance matching circuit 1 on the operating unit 108.

The control device 1 can also be designed to display on the operating unit 108 the measured values received by the first and/or second measuring unit 2, 3, such as the supply power or the output power. The determined overall efficiency can also be displayed by the control device 1 on the operating unit 108. The control device 1 is preferably designed to receive setpoint specifications, for example for the power of the RF signal, the frequency of the RF signal and/or the waveform of the RF signal, from the operating unit 108 and to generate corresponding actuating variables for the RF generator 101 and to transmit them thereto.

The control device 1 can be designed to change, in particular continuously, the frequency of the RF generator 101 during operation. The control device 1 can be further designed to check, in particular continuously, whether or not the overall efficiency improves after a frequency change.

The control device 1 can be designed to further change the frequency of the RF generator 101 in the same direction as in a previous change of the frequency if the overall efficiency has improved since the previous change of the frequency. If this is not the case, the control device 1 can be designed to change the frequency in the opposite direction.

The control device 1 can also be designed to select a step size with which the frequency of the RF generator 101 is changed, depending on a change in the overall efficiency. If the overall efficiency increases significantly after a frequency change (higher than a first threshold), the step size for the next frequency change can be increased. If the overall efficiency increases less after a frequency change (below a second or the first threshold), the step size for the next frequency change can be selected to be smaller.

In principle, it can be assumed that the control device 1 is only designed to set the frequency within a specific frequency range. Such a plausibility check can additionally or alternatively be carried out by the RF generator 101.

The control device 1 can also be designed to carry out the control for increasing the overall efficiency only if the overall efficiency falls below a certain level.

In FIG. 1, the control device 1 also includes an AI module 4. The AI module 4 is factory-trained to adjust the RF generator 101 and/or the impedance matching circuit 102 based at least on the supply power and the output power and optionally based on the plasma process such that the overall efficiency is increased. However, the use of an AI module 4 is optional.

The impedance matching circuit 102 is also designed to transform an input impedance at the input terminal 102a thereof to an output impedance at the output terminal 102b thereof. For this purpose, the impedance matching circuit 102 preferably comprises at least a first transformation stage 112a. In the exemplary embodiment shown in FIG. 1, the impedance matching circuit 102 comprises a first, second, and a third transformation stage 112a, 112b, 112c. The first transformation stage 112a is designed to transform an input impedance into a first intermediate impedance. The second transformation stage 112b is designed to transform the first intermediate impedance into a second intermediate impedance. The third transformation stage 112c is designed to transform the second intermediate impedance into an output impedance. The control device 1 is designed to control the impedance matching circuit 102 such that, for a predetermined input and output impedance, the transformation path of the first transformation stage 112a and/or the second transformation stage 112b and/or the third transformation stage 112c changes, wherein the control device 1 then redetermines the overall efficiency of the plasma process supply system after such a change. Preferably, the input impedance and output impedance remain unchanged. Only the transformation path from the input impedance to the first intermediate impedance or from the first intermediate impedance to the second intermediate impedance or from the second intermediate impedance to the output impedance changes. The impedance values of the first intermediate impedance and the second intermediate impedance can be changed.

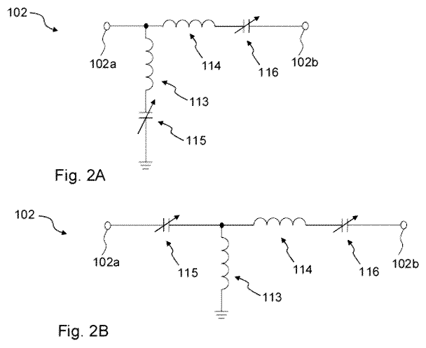

FIGS. 2 and 3 show various embodiments of the impedance matching circuit 102. The impedance matching circuit 102 can contain exactly one transformation stage 112a, which can be constructed according to the example of FIGS. 2A, 2B. If the impedance matching circuit 102 contains a plurality of transformation stages 112a, 112b, 112c, each transformation stage 112a, 112b, 112c can be constructed according to the exemplary embodiment of FIGS. 2A, 2B. It is understood that the impedance matching circuit 102 can also be configured differently than shown in FIGS. 2A, 2B.

The input terminal 102a of the impedance matching circuit 102 is connected in FIG. 2A to a first coil 113 (first inductance) and to a second coil 114 (second inductance). The first and second coils 113, 114 are connected with their first terminal to a common node and thus to the input terminal 102a of the impedance matching circuit 102. The first coil 113 is connected to a reference ground via a first capacitor 115 (first capacitance). The second coil 114 is connected to the output terminal 102b via a second capacitor 116 (second capacitance). The first and/or second capacitors 115, 116 are adjustable components, in particular in the form of rotary capacitors, the capacitance of which can be changed via stepper motors. Alternatively, solid-state switches can be used to add and remove capacitances as quickly as possible. In particular, the plate spacing of the first and second capacitors 115, 116 can be changed. The control device 1 is designed to control the respective stepper motors accordingly. The capacitances of the first and second capacitors 115, 116 can be adjusted independently of each other. Preferably, impedance matching circuit 102 is free of additional components. Of course, the position of the first coil 113 and the first capacitor 115 can also be exchanged. In this case, the first capacitor 115 is arranged at the input terminal 102a of the impedance matching circuit 102 and the first coil 113 is arranged at the reference ground. Additionally or alternatively, the position of the second coil 114 and the second capacitor 116 can also be exchanged. In this case, the second capacitor 116 is arranged at the input terminal 102a of the impedance matching circuit 102 and the second coil 114 is arranged at the output terminal 102b of the impedance matching circuit 102.

The input terminal 102a of the impedance matching circuit 102 is connected to the first capacitor 115 (first capacitance) in FIG. 2B. The first capacitor 115 is connected to both the first coil 113 (first inductance) and the second coil 114 (second inductance). This is done via a common node, to which both the first capacitor 115 and the first and second coils 113, 114 are connected. The first coil 113 is still connected to the reference ground. The second coil 114 is connected to the second capacitor 116 (second capacitance) (series connection). The second capacitor 116 is connected to the output terminal 102b of the impedance matching circuit 102. The position of the second coil 114 and the second capacitor 116 could also be reversed. In this case, the second capacitor 116 would be connected to the common node and the second coil 114 would be connected to the output terminal 102b of the impedance matching circuit 102. Preferably, the impedance matching circuit 102 is free of additional components.

FIGS. 3 and 4 show an exemplary embodiment of a possible structure of the second measuring unit 3. In principle, the first measuring unit 2 can be constructed identically or similarly to the second measuring unit 3. In this exemplary embodiment, the second measuring unit 3 is designed to measure a voltage and a current without contact.

For this purpose, the second measuring unit 3 comprises a current sensor 5 and a voltage sensor 6.

However, it is still preferable to measure the phase relationship between current and voltage so that the impedance can be calculated.

The current sensor 5 of the second measuring unit 3 is a coil, in particular in the form of a Rogowski coil. Both ends of the coil are preferably connected to each other via a shunt resistor 7. The voltage, which drops across the shunt resistor 7, can be digitized by means of a first A/D converter 8.

The voltage sensor 6 of the second measuring unit 3 is preferably built as a capacitive voltage divider. A first capacitor 9 is formed by an electrically conductive ring 9. An electrically conductive cylinder could also be used. The corresponding first and second cable connections 104a, 104b are guided through this electrically conductive ring 9. A second capacitor 10 of the voltage sensor 6, which is constructed as a voltage divider, is connected to the reference ground. A second A/D converter 11 is connected in parallel to the second capacitor 10 and is designed to detect and digitize the voltage which drops across the second capacitor 10.

In principle, the second measuring unit 3 can also be arranged or built on a (common) circuit board. The first capacitor 9 can be formed by a coating on a first and an opposite second side of the circuit board. In this case, the coatings on the first side and the second side are electrically connected to each other by vias. The first and second cable connections 104a, 104b are passed through an opening in the circuit board. The second capacitor 10 can be formed by a discrete component.

The current sensor 5 in the form of the coil, in particular in the form of the Rogowski coil, is further spaced apart from the first or second cable connection 104a, 104b than the first capacitor 9. The coil can also be formed on the same circuit board by corresponding coatings and vias. The coil for current measurement and the first capacitor for voltage measurement preferably run through a common plane.

The shunt resistor 7 can also be arranged on this circuit board. The same applies to the first and/or second A/D converter 8, 11.

The first and/or second measuring unit 2, 3 can also be designed as directional couplers.

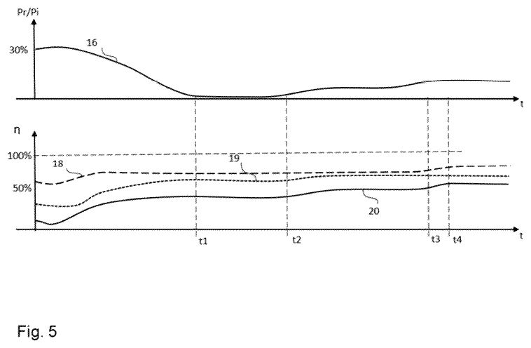

In FIG. 5, the temporal courses of some signals of such a plasma process supply system 100 in operation are shown as examples. In the upper graph, the course of the reflection factor Pr/Pi is shown in a curve 16 over time t. The lower graph shows the simultaneous progressions of different efficiencies η over time t. A first curve 18 can, for example, represent the efficiency curve of the impedance matching circuit 102. A second curve 19 can, for example, represent the course of the efficiency of the RF generator. A third curve 20 can, for example, represent the course of the overall efficiency of the plasma process supply system. The reflection factor moves from an initial value close to 30% to a value close to 0% at time t1. This could, for example, represent the course of events when the plasma process supply system 100 is switched on. At time t2, it rises slightly again, and at time t3, it increases slightly further, remaining constant but greater than 0% from time t4 onwards. Such behavior of a reflection factor is usually undesirable. According to the previous rules, it would actually be desirable for it to remain as close to 0% as possible throughout the entire operating time, as it does between times t1 and t2. However, according to the present disclosure, a different value is prioritized in the control, as will be explained again below.

Between the start and time t1, the efficiencies of the impedance matching circuit 102 and the RF generator 101 change, and thus does the overall efficiency of the plasma process supply system 100.

At time t2, the efficiency of the RF generator 101 begins to increase further by changing the setting of the RF generator 101 and/or the impedance matching circuit 102, in particular by changing the frequency of the RF generator 101. At the same time, the efficiency of the impedance matching circuit 102 remains constant. This need not necessarily be the case, but is presented here for the sake of clarity. This further increases overall efficiency. It is accepted that the reflection factor increases slightly at the same time. The trigger for this setting is the control device 1, which controls the RF generator 101 and/or the impedance matching circuit 102 accordingly.

At time t3, the efficiency of the impedance matching circuit begins to increase further by changing the setting of the RF generator 101 and/or of the impedance matching circuit 102, in particular by changing the frequency of the RF generator 101. At the same time, the efficiency of the RF generator 101 remains constant. This need not necessarily be the case, but is presented here for the sake of clarity. As a result, the overall efficiency increases further. It is accepted that the reflection factor increases slightly again at the same time. The trigger for this further adjustment is again the control device 1, which controls the RF generator 101 and/or the impedance matching circuit 102 accordingly.

From time t4 onwards, no further increase in overall efficiency can be achieved. No further improvement of the reflection factor can be achieved here without worsening the overall efficiency again. This setting is therefore retained.

In another exemplary embodiment, it is also provided that the reflection factor is close to or equal to zero in the time interval between t3 and t4, and this is nevertheless the time range in which the overall efficiency of the plasma process supply system is highest.

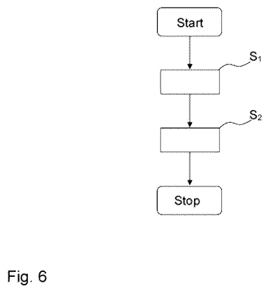

FIG. 6 describes the method according to an embodiment of the present disclosure for operating the control device 1 for controlling the plasma process supply system 100. In a first process step S₁, a supply power of the RF generator 101 and an output power of the impedance matching circuit 102 are determined. In a second process step S₂, the RF generator 101 is adjusted, in particular by changing the frequency of the RF generator 101 and/or the impedance matching circuit 102, so that an overall efficiency of the plasma process supply system 100, which results from the determined supply power of the RF generator 101 and the output power of the impedance matching circuit 102, is increased.

Embodiments of the present disclosure are not limited to the described exemplary embodiments. Within the scope of the present disclosure, all described and/or drawn features can be freely combined with one another.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A control device for controlling a plasma process supply system, comprising:
a radio-frequency (RF) generator; and
an impedance matching circuit configured for connection to a load, wherein the control device is configured to determine a supply power of the RF generator and an output power of the impedance matching circuit, wherein the control device is configured to change a frequency of the RF generator and/or to adjust the impedance matching circuit such that an overall efficiency of the plasma process supply system, which results from the determined supply power of the RF generator and the output power of the impedance matching circuit, is increased.

2. The control device according to claim 1, wherein the control device is configured to calculate the overall efficiency of the plasma process supply system based on the determined supply power and the output power.

3. The control device according to claim 1, wherein the control device is configured to continuously change the frequency of the RF generator during operation, and wherein the control device is further configured to continuously check whether or not the overall efficiency improves after a frequency change.

4. The control device according to claim 3, wherein the control device is configured to further change the frequency in a same direction based on a determination that the overall efficiency has improved, and/or
wherein the control device is configured to change the frequency in an opposite direction based on a determination that the overall efficiency has deteriorated.

5. The control device according to claim 3, wherein the control device is configured to select a step size by which the frequency is changed, depending on a change in the overall efficiency.

6. The control device according to claim 3, wherein the control device is configured to set the frequency only within a specific frequency range.

7. The control device according to claim 3, wherein the control device comprises an AI module which is factory-trained to change the frequency of the RF generator and/or adjust the impedance matching circuit at least based on the supply power and the output power.

8. The control device according to claim 3, wherein the control device is configured to change the frequency of the RF generator only when the overall efficiency exceeds a threshold value.

9. The control device according to claim 1, wherein the control device is configured to control the impedance matching circuit such that a transformation ratio between an input impedance of the impedance matching circuit and an output impedance of the impedance matching circuit are configured to be changed during operation, wherein the control device is further configured to check whether or not the overall efficiency improves after a change in the transformation ratio.

10. The control device according to claim 9, wherein the control device is configured to control the impedance matching circuit such that the input impedance and/or the output impedance remains unchanged when the transformation ratio changes.

11. The control device according to claim 1, wherein the supply power is active power and/or the output power is active power.

12. The control device according to claim 1, wherein the control device comprises a first measuring unit,
wherein the first measuring unit is configured to determine the supply power from an alternating voltage and an alternating current which can be obtained from a power grid and which is present at the input of a power supply unit of the RF generator or wherein the first measuring unit is configured to determine the supply power from a direct voltage and a direct current which are present at the output of the power supply unit of the RF generator and which serve to supply at least one RF amplifier of the RF generator.

13. The control device according to claim 1, wherein the control device comprises a second measuring unit,
wherein the second measuring unit comprises at least one directional coupler or a current sensor and a voltage sensor, and
wherein the control device is configured to determine the output power based on a measurement result of the at least one directional coupler or the current sensor and the voltage sensor.

14. The control device according to claim 13, wherein the second measuring unit is configured to be arranged at an output of the impedance matching circuit, or
wherein the second measuring unit is configured to be arranged at an input of the impedance matching circuit, and the control device is configured to determine the output power based on a current transformation ratio of the impedance matching circuit.

15. The control device according to claim 13, wherein the voltage sensor of the second measuring unit is a capacitive voltage divider,
wherein a first capacitance is formed by an electrically conductive ring or cylinder through which a cable, carrying RF power, is configured to be routed,
wherein the current sensor of the second measuring unit is a coil arranged around the conductive ring or cylinder.

16. The control device according to claim 1, wherein the control device is configured to determine a reflection factor at an output of the RF generator,
wherein the control device is configured to change the frequency of the RF generator and/or adjust the impedance matching circuit such that a reflection factor is reduced, and
wherein the control device is further configured to adjust the RF generator and/or the impedance matching circuit such that the reflection factor is increased when the overall efficiency improves at the same time.

17. A plasma process supply system, comprising:
the control device according to claim 1,
wherein the RF generator is connected to the impedance matching circuit via a first cable connection, and
wherein the impedance matching circuit is configured to be connected to a load in a form of a plasma chamber via a second cable connection.

18. The plasma process supply system according to claim 17, wherein the RF generator comprises at least one power supply and at least one RF amplifier,
wherein the at least one power supply comprises an input for connection to a power supply and an output for connection to the at least one RF amplifier,
wherein the at least one power supply is configured to convert an alternating voltage at the input into a direct voltage and to output the direct voltage at the output and to supply it to the at least one RF amplifier, and
wherein the control device is configured to determine a supply power at the input or at the output or between the input and the output.

19. The plasma process supply system according to claim 17, wherein the impedance matching circuit comprises at least one or more adjustable reactances to change the transformation ratio for an impedance between an input, to which the RF generator is connected, and an output, to which the load is configured to be connected, and
wherein the reactances are mechanically adjustable and/or electrically adjustable and are formed by at least one varactor and/or at least one switchable inductance and/or capacitance and/or by at least one PIN diode.

20. A method for operating the control device according to claim 1, comprising:
determining a supply power of the RF generator and determining an output power of the impedance matching circuit; and
setting the RF generator, by changing a frequency of the RF generator and/or the impedance matching circuit, so that an overall efficiency of a plasma process supply system, which results from the determined supply power of the RF generator and the output power of the impedance matching circuit, is increased.
